(19) United States
(12) Patent Application Publication
(10) Pub. No.: US 2010/0323524 A1
(43) Pub. Date: Dec. 23, 2010

(54) Method of etching the back side of a wafer

(75) Inventor: Masashi Yoshida, Miyazaki (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/801,594

(22) Filed: Jun. 16, 2010

(30) Foreign Application Priority Data
Jun. 18, 2009 (JP) 2009-144991

(51) Int. Cl. H01L 21/3065

(52) U.S. Cl. 438/710; 257/E21.218

(57) ABSTRACT

To etch the back side of a wafer, the front side of the wafer is first coated with a positive photoresist to form a protective film. The surface of the protective film is hardened by heating, or by heating and ultraviolet curing. The wafer is then placed in a plasma etching apparatus with the hardened surface of the protective film in contact with an electrode of the etching apparatus, and the back side of the wafer is patterned by plasma etching. When the etching is completed, the front side of the wafer is separated from the electrode and the wafer is removed from the plasma etching apparatus. The hardened positive photoresist prevents the wafer from sticking to the electrode.

### BACKGROUND OF THE INVENTION

1. Field of the Invention

The present invention relates to a method of etching the back side of a wafer in the manufacture of semiconductor devices, microelectromechanical systems, and the like.

2. Description of the Related Art

In microelectromechanical systems (MEMS), for example, electronic circuits are integrated with mechanical components such as sensors or actuators on a single substrate, which may be made of an inorganic material such as silicon or glass or an organic material such as a polymer material. Known MEMS devices include pressure sensors, touch sensors, and inertial sensors such as gyro sensors and accelerometers. A particularly small and simple MEMS device is the piezoresistive accelerometer, which is produced in large quantities for automotive applications.

A piezoresistive accelerometer includes, for example, a mass joined by flexible beams to one or more supporting members. Piezoresistors are formed in the beams. As the beams flex, the resistance of the piezoresistors changes and the resistance variations are converted to voltage signals by peripheral bridge circuits.

Piezoresistive accelerometers are often fabricated on a silicon on insulator (SOI) wafer. As shown in FIG. 1, the wafer has an insulating substrate layer 1 including a silicon dioxide (SiO₂) bottom layer 1a, a supporting silicon layer 1b typically three hundred to five hundred micrometers (300 μm to 500 μm) thick, an SiO₂ buried layer 1c, and a silicon active layer 2 disposed on the SiO₂ buried layer 1c. Piezoresistors 3 formed in the silicon active layer 2 are electrically interconnected by aluminum wiring 4 covered by a passivation film 5.

After the aluminum wiring 4 and passivation film 5 have been formed, the front surface of the wafer is covered by a photoresist material to form a protective film 6 as shown in FIG. 2. A negative photoresist, i.e., a photoresist that hardens on exposure to ultraviolet light, is conventionally used because of its high viscosity and adhesion and because it lends itself to the formation of a thick resist layer.

Referring to FIG. 3, the wafer is then turned over and placed on the lower electrode 10 of a plasma etching apparatus. The protective film 6 protects the silicon active layer 2 and the circuitry formed therein from direct contact with the lower electrode 10. A resist pattern (PR) 7 is formed on the back side of the wafer, and the parts left exposed by the resist pattern 7 are etched by a high-density plasma 8. The etch proceeds for several hundred micrometers through the SiO₂ bottom layer 1a and supporting silicon layer 1b to the SiO₂ buried layer 1c to form the masses and supporting members of a plurality of accelerometers. The beams are formed from the SiO₂ buried layer 1c and silicon active layer 2.

A description of the conventional piezoresistive accelerometer fabrication process can also be found in Japanese Patent Application Publication No. 2008-209207.

FIG. 4 shows the wafer resting on the lower electrode 10 after the resist pattern 7 has been formed. When the actual plasma etching begins, the heat of the high-density plasma 8 is conducted into the wafer in the direction of arrow A in FIG. 5. It takes considerable time to etch through several hundred micrometers of supporting substrate material 1b and reach the buried SiO₂ layer 1c. As the SOI wafer is exposed to the plasma for this extended time, its temperature gradually rises. Heat is accordingly conducted through the wafer into the protective film 6, which becomes softer and more viscous as it warms. Because of this softening, the surface layer 9 of the protective film 6 becomes an adhesive layer that causes the wafer to stick to the lower electrode 10. In addition, at the end of the etching process the supporting silicon layer 1b has been dissected into separate masses and supporting members held together by the SiO₂ buried layer 1c and silicon active layer 2, which are only a few micrometers thick, so the wafer as a whole has become highly flexible.

FIG. 6 shows the SIO wafer 1 resting on the lower electrode 10 at the end of the etching process, also showing the lift pins 12 that are used to remove the wafer 1 from the lower electrode 10. When the lift pins 12 are raised, they raise the edges of the wafer 1, but the center of the wafer 1 remains stuck to the surface of the lower electrode 10 because of the adhesion of the protective film 6, so the wafer flexes as shown in FIG. 7. As the lift pins 12 continue to rise, the wafer 1 eventually breaks free of the lower electrode 10 and springs back into shape with an impetus that flexes the wafer in the opposite direction. The impetus can be great enough to carry the entire wafer 1 off the lift pins 12, as shown in FIG. 8. When the wafer 1 falls back, one edge may land on the lower electrode 10 in front of the lift pins 12 as shown in FIG. 9, leaving the wafer 1 resting diagonally.

A robot transfer arm 13 now attempts to move into the space between the wafer 1 and the lower electrode 10 to carry the wafer 1 out of the plasma etching chamber, but if the wafer 1 is resting diagonally as in FIG. 9, the transfer arm 13 strikes the edge of the wafer 1 with a force that typically causes the wafer 1 to break at a point 14 near its center. Such occurrences reduce the yield of the fabrication process.

Even if the wafer 1 does not fall off the lift pins 12, a residue of negative photoresist remains on the surface of the lower electrode 10. Cleaning this residue off before the next wafer is etched takes time, reducing the throughput of the fabrication process.

Attempts by the inventor to solve these problems by baking the wafer after the protective film was applied were unsuccessful.

### SUMMARY OF THE INVENTION

An object of the present invention is to etch the back side of a wafer by use of plasma etching without having the wafer stick to the electrode on which it is placed in the plasma etching apparatus.

Another object is to improve the throughput and yield of a fabrication process that involves etching the back side of a wafer.

The invention provides a novel method of etching the back side of a wafer in a fabrication process. The method begins by coating the front side of the wafer with a positive photoresist to form a protective film. The protective film is then heated to dry the photoresist and harden the surface of the protective film. The photoresist may also be cured by exposure to ultraviolet light to further harden the protective film.

After these novel preparatory steps, the wafer is placed on an electrode of a plasma etching apparatus with the hardened surface of the protective film in contact with the electrode, and the back side of the wafer is patterned by plasma etching. When the etching is completed, the wafer is separated (e.g., lifted) from the electrode and removed from the plasma etching apparatus.

Use of a dried and hardened positive photoresist instead of the conventional negative photoresist avoids the problem of unwanted sticking of the front side of the wafer to the electrode. The wafer can accordingly be separated from the electrode by use of lift pins without the risk that the wafer will spring off the lift pins when it breaks free of the electrode.

The wafer can therefore be removed from the plasma etching apparatus by a conventional transfer arm without risk of wafer damage due to collision with the edge of the wafer. The yield of the fabrication process is thereby improved.

If the positive photoresist is cured by exposure to ultraviolet light, it forms a hard covering that protects the front surface of the wafer from damage due to contact with the electrode surface or contact with the transfer arm. The yield of the fabrication process is thereby further improved.

The plasma etching apparatus also requires less cleaning after the etching process, because no residual photoresist is left on the electrode. The throughput of the fabrication process is thereby improved.

### BRIEF DESCRIPTION OF THE DRAWINGS

In the attached drawings:

FIGS. 1, 2, and 3 illustrate a conventional process for fabricating an MEMS device;

FIGS. 4, 5, 6, 7, 8, 9, and 10 illustrate the conventional back side etching step in FIG. 3 in further detail, and show an ensuing problem;

FIGS. 11, 12, 13, 14, 15, and 16 illustrate a novel back side etching step and show how the problem is solved; and

FIGS. 17, 18, 19, 20, 21, and 22 illustrate another novel back side etching step.

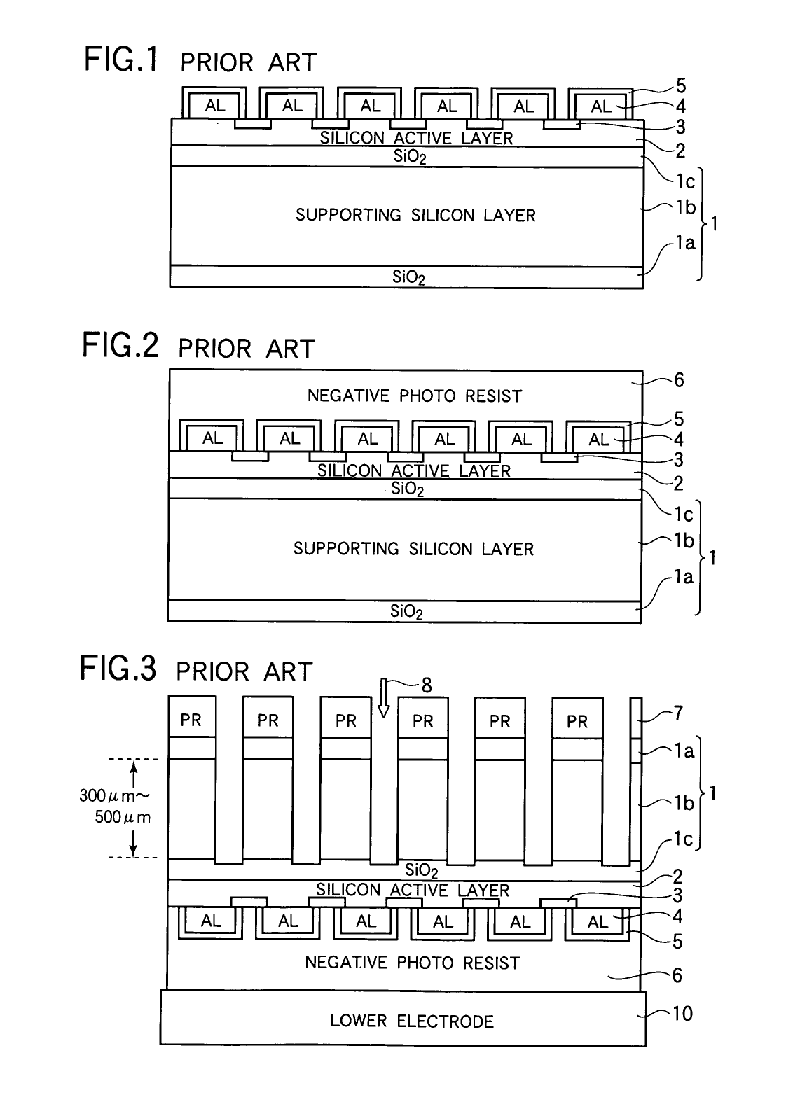

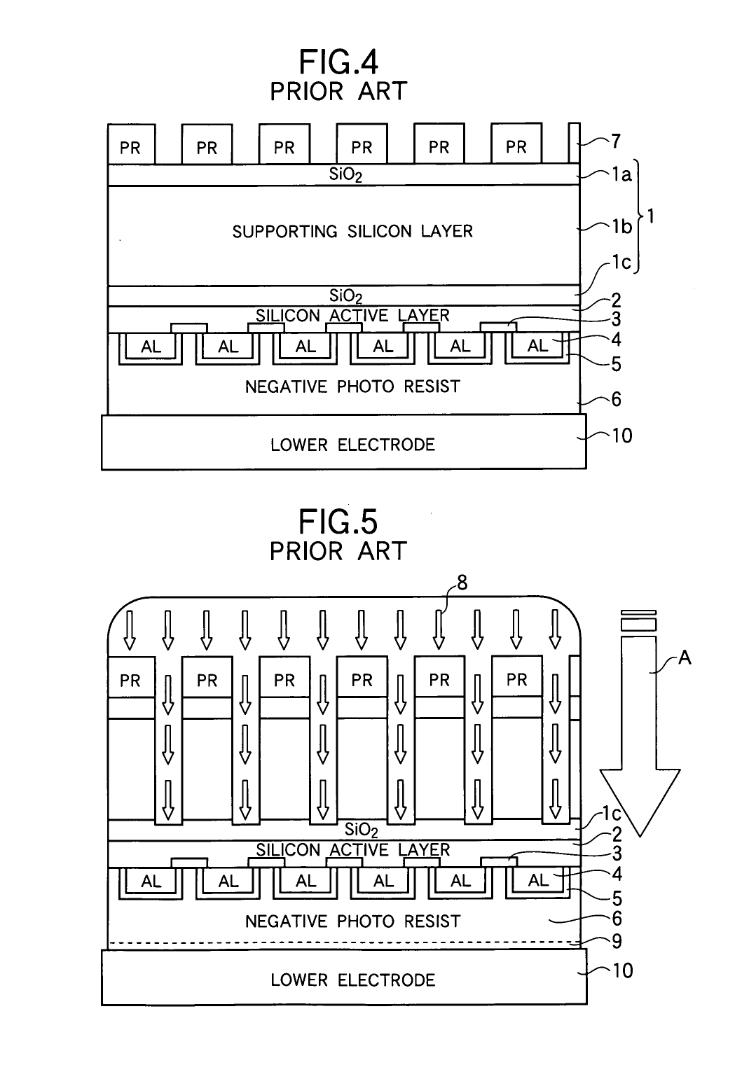

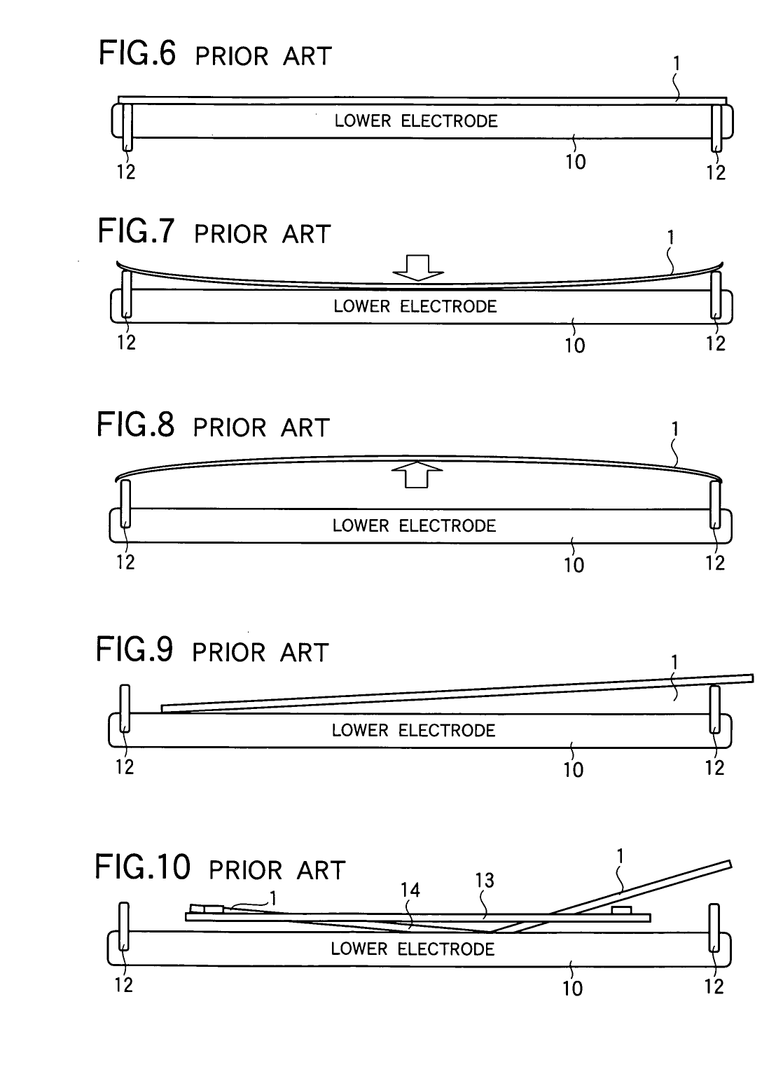

### DETAILED DESCRIPTION OF THE INVENTION

Embodiments of the invention will now be described with reference to the attached non-limiting drawings, in which like elements are indicated by like reference characters.

### First Embodiment

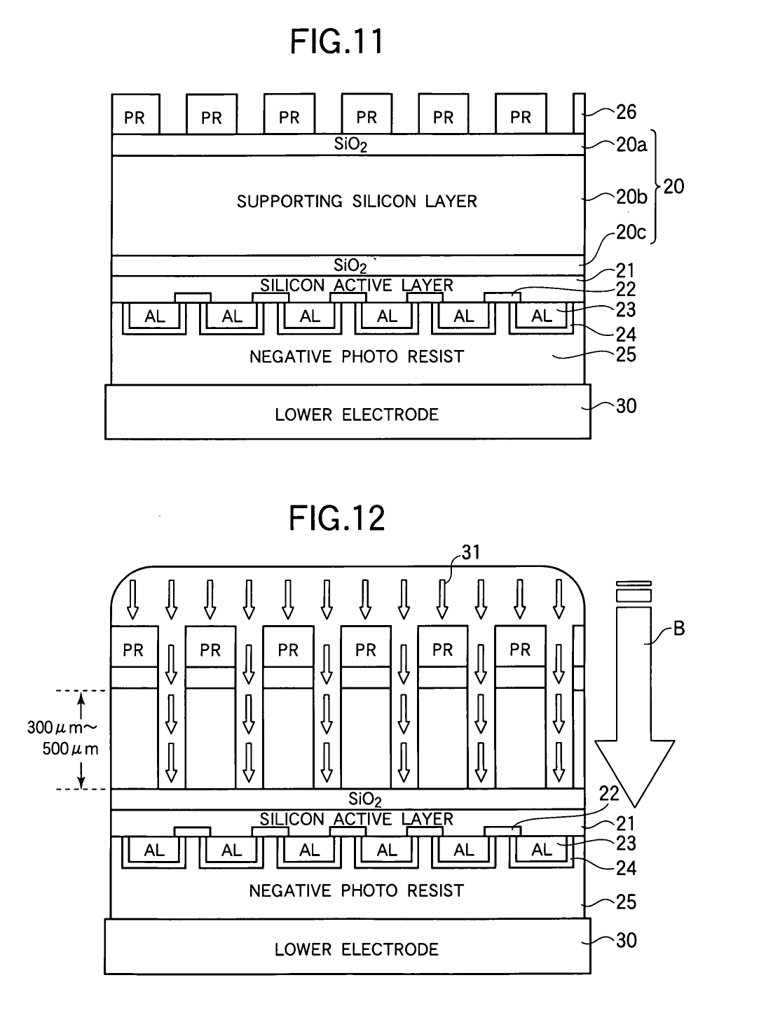

In the first embodiment, the back side of, for example, an SOI wafer 20 is etched as shown in FIGS. 11 and 12 to form a plurality of piezoresistive accelerometers. The SOI wafer 20 has an SiO₂ bottom layer 20a on which a silicon (Si) supporting layer 20b and an SiO₂ buried layer 20c are formed. A silicon active layer 21 is disposed on the SiO₂ buried layer 20c, and a plurality of piezoresistors 22 are formed in the silicon active layer 21. The piezoresistors 22 are electrically interconnected by metal wiring 23 (aluminum wiring, for example, indicated as AL in the drawings) coated with a passivation film 24 for protection from moisture.

The passivation film 24 on the front side of the SOI wafer 20 is coated with a layer of positive photoresist to form a protective film 25. Known positive photoresists that can be used include photosensitive compounds with quinone diazide groups. The wafer is then turned over and placed on the lower electrode 30, and the SiO₂ bottom layer 20a and the supporting silicon layer 20b on the back side of the SOI wafer 20 are etched by high-density plasma 31 through a resist pattern 26 used as a mask. The etched supporting silicon layer 20b forms the mass and supporting members of a plurality of accelerometers, and the silicon active layer 21, including the piezoresistors 22, forms the flexible beams. The piezoresistors 22 are interconnected by the metal wiring 23 to form bridge circuits.

The piezoresistive accelerometers in the first embodiment thus include masses and supporting members formed with predetermined spacing by etching the supporting silicon layer 20b, interconnected by flexible beams formed from silicon active layer 21, and piezoresistors 22 formed in the flexible beams.

In an accelerometer having this structure, when the accelerometer is accelerated, a compressive force applied to the flexible beams alters the resistance of the piezoresistors 22. The resistance changes are detected as voltage signals by the bridge circuits formed by the piezoresistors 22.

The piezoresistive accelerometer fabrication process will now be described in more detail. A wafer preparation step (a), an etching step (b), and a wafer removal step (c) will be described.

(a) Referring to FIG. 11, in the wafer preparation step, first an SOI wafer 20 is obtained. The SOI wafer 20 has a SiO₂ bottom layer 20a that functions as a back side insulating layer. A supporting silicon layer 20b typically 300 μm to 500 μm thick is formed on the SiO₂ bottom layer 20a, and a SiO₂ buried layer 20c is formed on the supporting silicon layer 20b. The SiO₂ buried layer 20c functions as a front side insulating layer. A silicon active layer 21 is formed on the SiO₂ buried layer 20c by chemical vapor deposition (CVD), for example, and a plurality of piezoresistors 22 are formed in the silicon active layer 21. The surface of the silicon active layer 21 is then metalized, with aluminum, for example, and the metal layer is patterned by photolithography to form metal wiring 23 that interconnects the piezoresistors 22 to form bridge circuits. A passivation film 24 is then formed by CVD, for example, to cover the metal wiring 23.

Before the back side of the SOI wafer 20 is processed, a protective film 25 is formed by using a spin-coater, for example, to coat the front side silicon active layer 21 with a positive photoresist such as the compound including quinone diazide groups mentioned above.

After this coating process, the protective film 25 is dried by heating. For example, the protective film 25 may be post-baked at 120° C. The baking time should be at least fifteen minutes, preferably about half an hour or so. The heat hardens the surface of the protective film 25.

In order to process the back side of the supporting silicon layer 20b, the SOI wafer 20 is turned over and its front surface is placed in contact with the lower electrode 30 of an etching apparatus. The SOI wafer 20 is held in this position by vacuum suction. The hardened protective film 25 on its front surface protects the electrical circuitry formed in and on the silicon active layer 21 from being damaged by contact with the lower electrode 30. Another photoresist is applied to the SiO₂ bottom layer 20a on the back side of the SOI wafer 20, and this photoresist is patterned by photolithography to form a resist pattern 26 for use as an etching mask.

(b) Referring to FIG. 12, in the etching step, the SiO₂ bottom layer 20a and the supporting silicon layer 20b are etched to a depth of several hundred micrometers by plasma etching through the resist pattern 26, using a high-density plasma 31. During this etching process proceeds, heat is gradually transferred from the high-density plasma toward the SiO₂ buried layer 20c as indicated by arrow B, and the temperature of the whole SOI wafer rises. In particular, the temperature of the protective film 25 on the front side of the SOI wafer rises.

However, since the protective film 25 is formed from a positive photoresist and its surface has already been hardened by post-baking, the resist surface does not soften or adhere to the lower electrode 30. When the etching ends, although the separated parts of the etched supporting silicon layer 20b are left sitting on the silicon active layer 21, which is only several micrometers thick, the SOI wafer 20 does not flex as it is often observed to do in the conventional fabrication process.

The etched supporting silicon layer 20b forms the accelerometer masses and their supporting members, and the silicon active layer 21, including the piezoresistors 22, forms the flexible beams of the accelerometers.

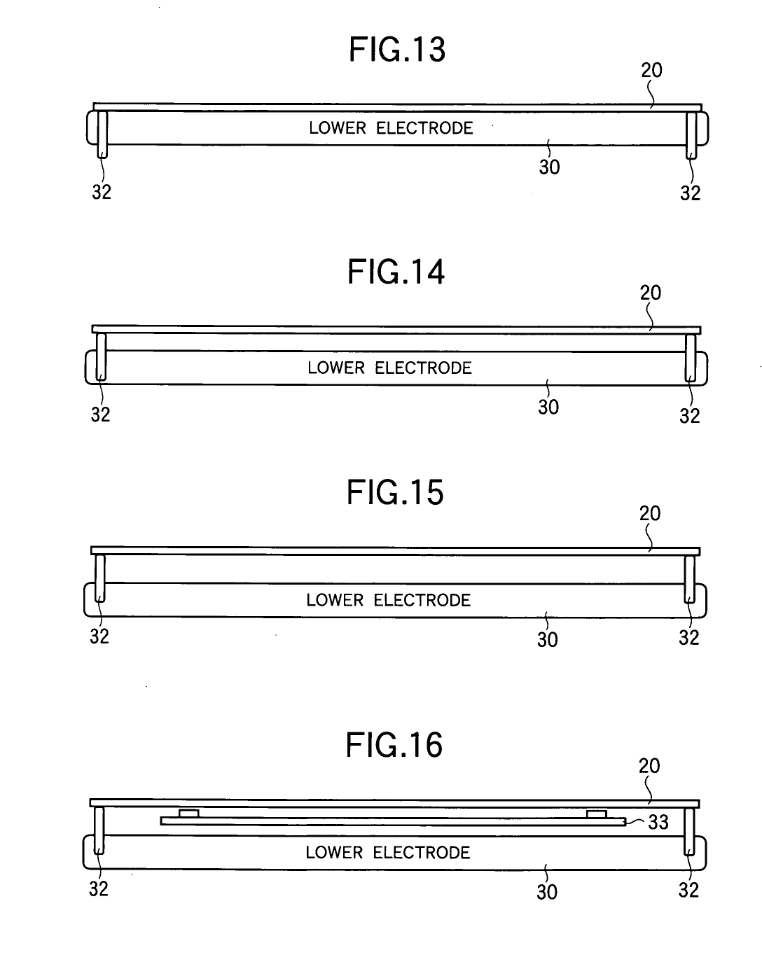

(c) At the end of the etching step, the SOI wafer 20 is resting on the lower electrode 30 as shown in FIG. 13, held by vacuum suction with the lift pins 32 of the plasma etching apparatus retracted. Referring to FIG. 14, in the wafer removal step, to remove the SOI wafer 20 from the plasma etching apparatus, the SOI wafer 20 is lifted by the lift pins 32 to detach its front surface from the lower electrode 30. Since the protective film 25 on the front side of the SOI wafer 20 does not adhere to the lower electrode 30, the SOI wafer 20 can be lifted smoothly to the position shown in FIG. 15, remaining seated on the lift pins 32 throughout the lifting process.

Referring next to FIG. 16, a transfer arm 33 is inserted between the SOI wafer 20 and the lower electrode 30 to remove the SOI wafer 20. The transfer arm 33 can be inserted without colliding with the SOI wafer 20, which remains in its expected position on the lift pins 32. After being inserted, the transfer arm 33 is raised to lift the SOI wafer 20 off the lift pins 32 and carries the SOI wafer 20 away from the lower electrode 30 to the next processing station, where the SOI wafer 20 is washed and other finishing processes are carried out.

By using a positive photoresist instead of the conventional negative photoresist for the protective film 25, the first embodiment avoids adhesion of the wafer to the lower electrode 30 and wafer breakage during the wafer removal process, thereby improving the yield of the wafer fabrication process. The fabrication process also requires less post-etching cleaning than in the conventional back side etching process, because no residual photoresist is left on the lower electrode, so the throughput of the fabrication process is also improved.

### Second Embodiment

In the second embodiment, piezoresistive accelerometers are fabricated in the same way as in the first embodiment except that an additional ultraviolet curing process is performed. The description will again be divided into a wafer preparation step (a), an etching step (b), and a wafer removal step (c).

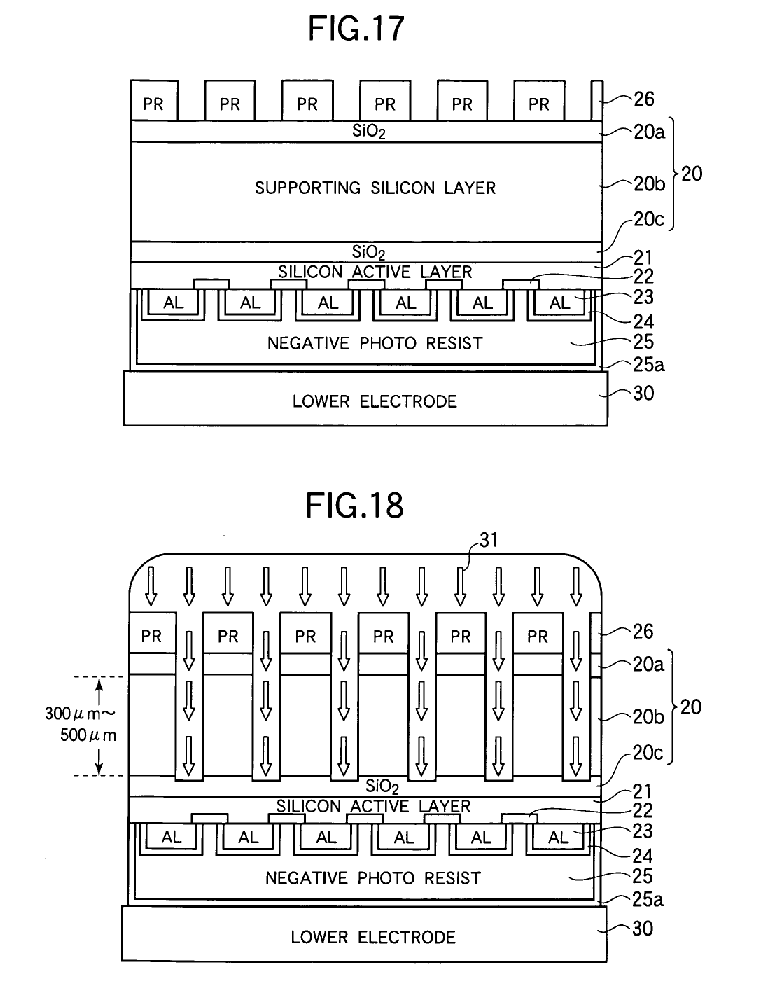

(a) Referring to FIG. 17, a SOI wafer 20 is prepared as in the first embodiment by forming piezoresistors 22 in the silicon active layer 21 on the front side, forming metal wiring 23 on the surface of the silicon active layer 21, and coating the surface with a passivation film 24.

Before processing the back side of the supporting silicon layer 20b, a protective film 25 is formed by coating the front side of the wafer with a positive photoresist to protect the front side silicon active layer 21 and its piezoresistors 22 and metal wiring 23. The protective film 25 is dried by heating (for example, post-baked at 120° C. for about half an hour), which also hardens the surface of the protective film 25. In addition, in the second embodiment, the protective film 25 is further hardened by exposure to ultraviolet light; that is, it undergoes a UV curing process. This process forms a hard shell 25a on the surface of the protective film 25.

In order to process the back side of the supporting silicon layer 20b, the SOI wafer 20 is placed with its front surface on the lower electrode 30 of an etching apparatus as in the first embodiment. The hard shell 25a of the protective film 25 makes contact with the lower electrode 30, providing even better protection than in the first embodiment for the electrical circuitry formed in and on the silicon active layer 21. A resist pattern 26 is formed on the back side of the wafer, on the SiO₂ bottom layer 20a, as in the first embodiment.

(b) Referring to FIG. 18, in the etching step, the SiO₂ bottom layer 20a and the supporting silicon layer 20b are etched to a depth of several hundred micrometers as in the first embodiment, using a high-density plasma 31. Although the temperature of the front side of SOI wafer rises, since the protective film 25 has a hard outer shell 25a formed by post-baking and UV curing, no adhesion occurs between the SOI wafer 20 and the lower electrode 30.

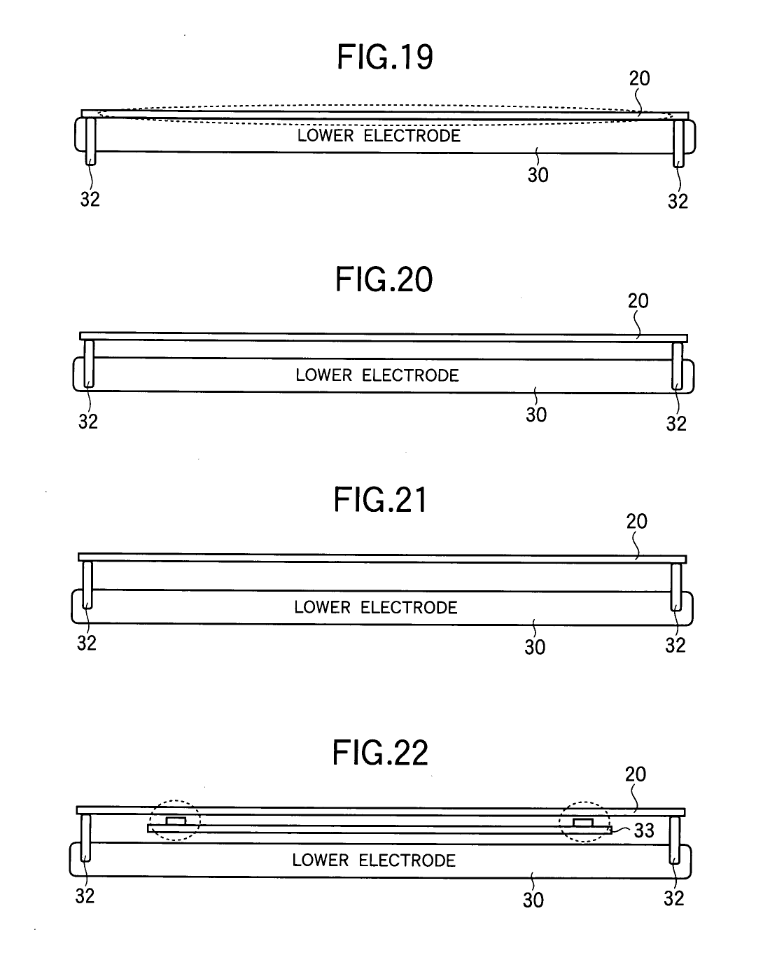

(c) Referring to FIG. 19, at the end of the etching step, the SOI wafer 20 is resting on the lower electrode 30 as in the first embodiment, held by vacuum suction with the lift pins 32 of the plasma etching apparatus retracted. Even if the wafer was poorly handled when placed on the lower electrode 30, as indicated by the dashed line, its front surface remains undamaged because of the improved protection offered by the hard shell formed on the surface of the protective film.

The SOI wafer 20 is now lifted from the lower electrode 30 by the lift pins 32 as shown FIGS. 20 and 21. The wafer 20 lifts easily, since the hard shell on its protective film has no tendency to stick to the lower electrode 30.

Referring next to FIG. 22, a transfer arm 33 is inserted between the SOI wafer 20 and the lower electrode 30 to remove the SOI wafer 20. As in the first embodiment, the transfer arm 33 can be inserted without colliding with the wafer 20. In addition, when the transfer arm carries the wafer 20 away from the lower electrode 30 to undergo further processing such as washing, although the transfer arm makes contact with the wafer 20 in the areas indicated by the dashed lines, the wafer is protected by the hard shell formed on the surface of its protective film, so it is not scratched or otherwise marred.

In the second embodiment, the additional UV curing process thus provides enhanced protection from damage during removal of the wafer from the etching apparatus and transfer to the next processing station, as well as when the wafer is carried into the etching apparatus.

The invention is not limited to the embodiments described above. Two exemplary variations (A) and (B) will be described next.

(A) When the invention is practiced in the fabrication of an accelerometer, the accelerometer structure, materials, and fabrication process are not limited to the structure, materials, and fabrication process described above. For example, the wafer need not be an SOI wafer but may be some other type of wafer.

(B) The novel back side etching process can be applied in the fabrication of devices other than accelerometers. The invention is applicable to MEMS fabrication processes in general, and to semiconductor device fabrication processes that require back side etching

Those skilled in the art will recognize that further variations are possible within the scope of the invention, which is defined in the appended claims.

What is claimed is:

1. A method of etching the back side of a wafer having a front side and a back side, the method comprising:
coating the front side of the wafer with a positive photoresist to form a protective film;
heating the protective film to dry the photoresist, thereby hardening a surface of the protective film;
placing the wafer on an electrode of a plasma etching apparatus with the front side of the wafer facing the electrode and the hardened surface of the protective film in contact with the electrode;
patterning the back side of the wafer by plasma etching;
separating the front side of the wafer from the electrode; and
removing the wafer from the plasma etching apparatus.

2. The method of claim 1, further comprising curing the protective film with ultraviolet light to further harden the surface of the protective film after the heating of the protective film.

3. The method of claim 1, wherein separating the front side of the wafer from the electrode further comprises using lift pins to push the wafer away from the electrode, and removing the wafer from the plasma etching apparatus further comprises:
inserting a transfer arm between the wafer and the electrode; and
carrying the wafer away from the electrode on the transfer arm.

4. The method of claim 1, wherein patterning the back side of the wafer further comprises creating a structure for use in a microelectromechanical system.

5. The method of claim 1, wherein patterning the back side of the wafer further comprises creating a structure for use in a piezoresistive accelerometer.

6. The method of claim 1, wherein patterning the back side of the wafer further comprises creating a structure for use in a semiconductor device.

7. The method of claim 1, wherein the positive photoresist includes a quinone diazide group.

8. The method of claim 1, wherein heating the protective film further comprises baking the protective film at substantially 120° C.

9. The method of claim 1, wherein heating the protective film further comprises baking the protective film for at least fifteen minutes.
